(19) United States
(12) Patent Application Publication
(10) Pub. No.: US 2018/0226651 A1
(43) Pub. Date: Aug. 9, 2018

(54) GRAPHENE ELECTRODE

(71) Applicant: Sichuan Keyuan Landscape Project Co., Ltd, Sichuan (CN)

(72) Inventors: Mingchun Hu, Sichuan (CN); Juntao Hu, Sichuan (CN); Fangyu Fan, Sichuan (CN)

(21) Appl. No.: 15/863,690

(22) Filed: Jan. 5, 2018

(30) Foreign Application Priority Data
Feb. 5, 2017 (CN) 201720109903.2

(51) Int. Cl. H01M 4/62; H01M 4/66; H05K 9/00

(52) U.S. Cl. CPC H01M 4/625; H05K 9/0081; H01M 4/663

(57) ABSTRACT

The invention discloses a graphene electrode structurally comprising graphene and an electrode, the graphene being connected to the electrode. The graphene comprises a carbon edge, a lattice, a carbon fiber, an electromagnetic shielding layer and a discharge dialysis layer, the carbon edge being provided with the lattice, the lattice being provided with the carbon fiber and the carbon edge being provided with the discharge dialysis layer. The electrode comprises a lead wire, a metal cap, an insulating filler, an inflaming wire 1, a glass film and a glass pipe, the metal cap being arranged above the glass pipe, the insulating filler being arranged inside the glass pipe, the lead wire being connected to the inflaming wire, the glass pipe being provided with the glass film. The invention has beneficial effects in that, by connecting graphene with an electrode, the toughness of the electrode is strengthened and the fracture rate of the electrode is reduced.

### TECHNICAL FIELD

The invention relates to a graphene electrode in the field of electrodes.

### BACKGROUND

An electrode in an electrochemical reactor is in a heart potential. It is the place where electrons are received or supplied in the electrochemical reaction, and the potential change of the electrode restricts the direction and limit of the electron transfer reaction. An electrode is composed of a series of phases contacting each other, with one end being an electronic conductor of metal-coated graphite or semiconductor, and the other end being an ionic conductor of electrolyte.

Chinese Application No. 01264770.5 discloses a metal/non-metal composite carbon electrode in the prior art. According to the invention, a metal cylinder is arranged outside a carbon electrode, and the utility mode is coated with a layer of steel plate, which improves the performance of the electrode in tensile strength, bending strength and oxidation resistance when heated, so that crack, chipping and fracture are avoided and the yield is increased by 10%. The existing electrode fails to strengthen its toughness and reduce its fracture rate.

### SUMMARY

In view of the defects of the prior art, the object of the invention is to provide a graphene electrode, which solves the problem that the prior electrode fails to strengthen its toughness and reduce its fracture rate.

In order to realize the above object, the invention is carried out by the following technical solution: a graphene electrode structurally comprises graphene and an electrode, the graphene being connected to the electrode. The graphene comprises a carbon edge, a lattice, a carbon fiber, an electromagnetic shielding layer and a discharge dialysis layer, the carbon edge being provided with the lattice, the lattice being provided with the carbon fiber and the carbon edge being provided with the discharge dialysis layer. The electrode comprises a lead wire, a metal cap, an insulating filler, an inflaming wire, a glass film and a glass pipe, the metal cap being arranged above the glass pipe, the insulating filler being arranged inside the glass pipe, the lead wire being connected to the inflaming wire, and the glass pipe being provided with the glass film.

Further, the electromagnetic shielding layer is connected to the discharge dialysis layer.

Further, the carbon edge is provided with the electromagnetic shielding layer.

Further, the lattice is provided with the electromagnetic shielding layer.

Further, the lead wire penetrates through the metal cap.

Further, the insulating filler is provided with magnetic beads.

Further, the insulating filler is provided with carbon particles.

### BENEFICIAL EFFECT

The invention provides a graphene electrode, the graphene being connected to the electrode, wherein the graphene comprises a carbon edge, a lattice, a carbon fiber, an electromagnetic shielding layer and a discharge dialysis layer, the carbon edge being provided with the lattice, the lattice being provided with the carbon fiber and the carbon edge being provided with the discharge dialysis layer, and the electrode comprises a lead wire, a metal cap, an insulating filler, an inflaming wire, a glass film and a glass pipe. By connecting the graphene with the electrode, the toughness of the electrode is strengthened and the fracture rate of the electrode is reduced.

### BRIEF DESCRIPTION OF THE DRAWINGS

Other features, objects and advantages of the invention will become clearer through the detailed description of the non-limiting embodiments with reference to the following drawings.

FIG. 1 is a structural diagram of graphene in the invention; and

FIG. 2 is a structural diagram of an electrode in the invention.

In the drawings, graphene-1, electrode-2, carbon edge-3, lattice-4, carbon fiber-5, magnetic shielding layer-6, discharge dialysis layer-7, lead wire-8, metal cap-9, insulating filler-10, inflaming wire-11, glass film-12, and glass pipe-13.

### DETAILED DESCRIPTION

In order to make the technical means, creation features, objects and effects of the invention easier to understand, the invention will be further described in combination with embodiments.

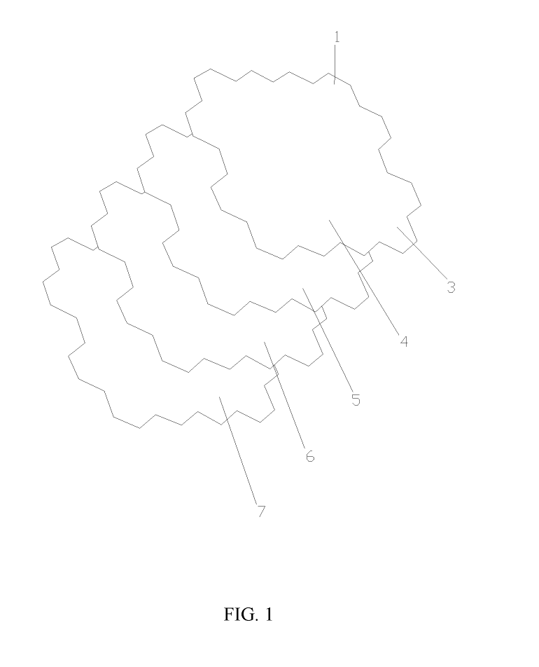

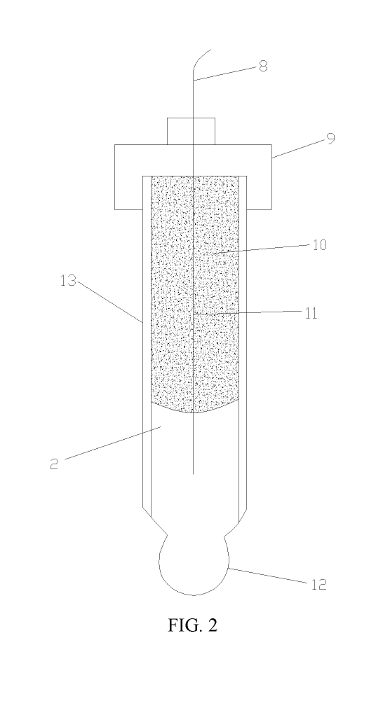

Referring to FIG. 1 and FIG. 2, the invention provides a technical solution: a graphene electrode structurally comprises graphene 1 and an electrode 2, the graphene 1 being connected to the electrode 2. The graphene 1 comprises a carbon edge 3, a lattice 4, a carbon fiber 5, an electromagnetic shielding layer 6 and a discharge dialysis layer 7, the carbon edge 3 being provided with the lattice 4, the lattice 4 being provided with the carbon fiber 5, and the carbon edge 3 being provided with the discharge dialysis layer 7. The electrode 2 comprises a lead wire 8, a metal cap 9, an insulating filler 10, an inflaming wire 11, a glass film 12 and a glass pipe 13, the metal cap 9 being arranged above the glass pipe 13, the insulating filler 10 being arranged inside the glass pipe 13, the lead wire 8 being connected to the inflaming wire 11, the glass pipe 13 being provided with the glass film 12, the electromagnetic shielding layer 6 being connected to the discharge dialysis layer 7, the carbon edge 3 being provided with the electromagnetic shielding layer 6, and the lead wire 8 penetrating through the metal cap 9. The invention has beneficial effects in that, by connecting graphene with an electrode, the toughness of the electrode is strengthened and the fracture rate of the electrode is reduced.

When in use, the electrode is soaked in an aqueous solution for a while before use. After soaking, a hydration layer contacts with the solution to form an activity difference and establish a balance as a whole, and the lead wire allows charges of a two-phase interface to be distributed to generate a certain phase boundary potential.

It's like a protection film of a mobile phone adopts a tempered layer to provide a maximum protection for the screen.

The above shows and describes the basic principle and main features of the invention as well as its advantages, it is obvious for those skilled in the art that the invention is not limited to the details of the above exemplary embodiments, and can be carried out in other specific implementations without departing from the spirit or basic features of the invention. Thus, no matter from what points of view, any embodiments should be considered to be exemplary and non-limitative, the scope of the invention is defined by the appended claims rather than the above description, and thus, it is intended that all the variations falling within the concepts and scopes of equivalent elements of the claims are included in the invention. All reference signs in the claims should not be considered as limiting the involved claims.

In addition, it should be understood that although this specification is described according to embodiments, not every embodiment contains only one independent technical solution, such a description manner of the specification is merely for clarity, those skilled in the art should consider the specification as a whole and technical solutions in each embodiment may also be properly combined to form other embodiments which can be understood by those skilled in the art.

1. A graphene electrode structurally comprising graphene (1) and an electrode (2), the graphene (1) being connected to the electrode (2), wherein the graphene (1) comprises a carbon edge (3), a lattice (4), a carbon fiber (5), an electromagnetic shielding layer (6) and a discharge dialysis layer (7), the carbon edge (3) being provided with the lattice (4), the lattice (4) being provided with the carbon fiber (5) and the carbon edge (3) being provided with the discharge dialysis layer (7), and the electrode (2) comprises a lead wire (8), a metal cap (9), an insulating filler (10), an inflaming wire (11), a glass film (12) and a glass pipe (13), the metal cap (9) being arranged above the glass pipe (13), the insulating filler (10) being arranged inside the glass pipe (13), the lead wire (8) being connected to the inflaming wire (11) and the glass pipe (13) being provided with the glass film (12).

2. The graphene electrode according to claim 1, wherein the electromagnetic shielding layer (6) is connected to the discharge dialysis layer (7).

3. The graphene electrode according to claim 1, wherein the carbon edge (3) is provided with the electromagnetic shielding layer (6).

4. The graphene electrode according to claim 1, wherein the lattice (4) is provided with the electromagnetic shielding layer (6).

5. The graphene electrode according to claim 1, wherein the lead wire (8) penetrates through the metal cap (9).
